(19) United States
(12) Patent Application Publication
(10) Pub. No.: US 2016/0088720 A1
(43) Pub. Date: Mar. 24, 2016

(54) TRANSISTOR THERMAL AND EMI MANAGEMENT SOLUTION FOR FAST EDGE RATE ENVIRONMENT

(71) Applicant: HIQ SOLAR, INC., Santa Clara, CA (US)

(72) Inventor: Andre P. WILLIS, Palo Alto, CA (US)

(21) Appl. No.: 14/850,202

(22) Filed: Sep. 10, 2015

Related U.S. Application Data
(60) Provisional application No. 62/054,504, filed on Sep. 24, 2014.

(51) Int. Cl. H05K 1/02; H05K 3/30; H05K 1/18; H01L 23/367; H01L 23/552

(52) U.S. Cl. CPC H05K 1/0206; H01L 23/3675; H01L 23/552; H05K 1/181; H05K 3/30; H05K 2201/10166

(57) ABSTRACT

An electronic device mounting technique in which insulative and thermal barrier materials used in combination with printed circuit board design produce higher electrical breakdown voltage while minimizing thermal resistance and electromagnetic interference.

### BACKGROUND

The present invention relates to transistors mounted for operation in a fast edge rate signal environment without electrical device breakdown, and in particular to transistors mounted such that they simultaneously have low thermal resistance and high containment of electrical fields to reduce electromagnetic interference (EMI).

Thermal management of transistors is usually achieved by attaching the thermal tab of the transistor to a heat sink. The thermal tab of the transistor is often electrically connected to one of the electrodes, and therefore it is frequently desirable to electrically insulate the transistor case from the heat sink. It is also desirable for the insulating material to have the lowest thermal resistance possible, while exhibiting high electrical resistance.

When the transistor is used in a circuit where switching edge speeds are high (for example 100V/ns edge rates) and the thermal tab is electrically connected to nodes with high edge rates, these high edge rates have the effect of lowering the electrical breakdown voltage of normally utilized insulating materials. In addition, high switching speeds and fast edge rates can be a cause of electromagnetic interference (EMI), which is usually undesirable and must be managed.

Circuit design, circuit board layout and choice of thermal materials are a trade-off in order to optimize thermal conductivity, EMI and electrical breakdown. The combined effect of the methods described here achieves this.

### SUMMARY

In accordance with the presently claimed invention, an electronic device mounting technique is provided in which insulative and thermal barrier materials used in combination with printed circuit board design produce higher electrical breakdown voltage while minimizing thermal resistance and electromagnetic interference.

In accordance with one embodiment of the presently claimed invention, an electronic device mounted on a circuit substrate for fast signal edge rate operation includes:

a metal member;

a printed circuit substrate mechanically coupled to the metal member and including
an electrically insulative substrate with mutually opposed first and second substrate sides, and
a first electrically conductive layer disposed on the first substrate side; and

a semiconductor device including at least first and second electrodes with
the first electrode electrically coupled to a portion of the first electrically conductive layer, and
the second electrode mechanically coupled via at least a layer of dielectric material to one or both of the printed circuit substrate and metal member.

In accordance with another embodiment of the presently claimed invention, a method of mounting an electronic device on a circuit substrate for fast signal edge rate operation includes:

mechanically coupling a printed circuit substrate to a metal member, wherein the printed circuit substrate includes
an electrically insulative substrate with mutually opposed first and second substrate sides, and
a first electrically conductive layer disposed on the first substrate side;

electrically coupling a first electrode of a semiconductor device to a portion of the first electrically conductive layer; and

mechanically coupling a second electrode of the semiconductor device via at least a layer of dielectric material to one or both of the printed circuit substrate and metal member.

### BRIEF DESCRIPTION OF THE DRAWINGS

FIG. 1 depicts a transistor mounting implementation in accordance with an exemplary embodiment of the presently claimed invention.

FIGS. 2A-2C depicts a transistor mounting implementation in accordance with another exemplary embodiment of the presently claimed invention.

FIGS. 3A-B depict a half bridge circuit and its operation.

FIGS. 4A-4D depict an exemplary layout of a half bridge circuit using transistor mounting in accordance with exemplary embodiments of the presently claimed invention.

### DETAILED DESCRIPTION

The following detailed description is of example embodiments of the presently claimed invention with references to the accompanying drawings. Such description is intended to be illustrative and not limiting with respect to the scope of the present invention. Such embodiments are described in sufficient detail to enable one of ordinary skill in the art to practice the subject invention, and it will be understood that other embodiments may be practiced with some variations without departing from the spirit or scope of the subject invention.

1. Transistor Mounting

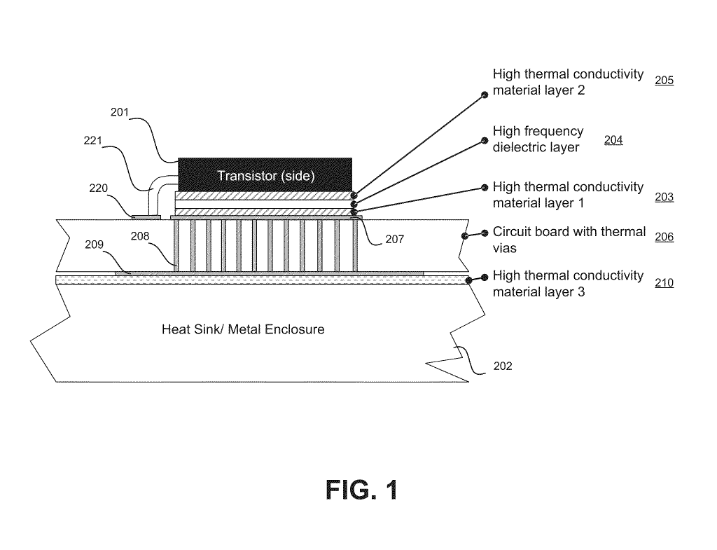

The transistor mounting implementation is shown in FIG. 1. The transistor (201) is attached to a printed circuit board (PCB) (206). The legs (example 221) of the transistor (201) are cut short, bent down and soldered to a conductive trace area (220). Between transistor (201) and PCB (206) are three layers of thermal materials (205, 204, 203). The PCB (206) is attached to the heat sink (202) with a high thermal conductivity material layer (210) to electrically isolate it from the heat sink (202) while providing low thermal impedance. The PCB (206) has local areas of electrically conductive traces (207, 209) on either side of the PCB (206) immediately below the body of the transistor (201). The local areas of electrically conductive traces are connected through the body of the PCB (206) with thermally and electrically conductive vias (208).

The implementation of FIG. 1 is arranged such that the conductive trace areas (207, 209) and vias (208) may be coupled to circuit ground. This has the advantage that even if the heat sink (202) is not connected to circuit ground, electric field radiated by the transistor (201) couples to ground rather than to the heat sink/metal enclosure (202), reducing electromagnetic interference (EMI). The design ensures the distance between the transistor (201) and circuit ground of the conductive trace area (207) is short, further containing any electric field and minimizing EMI.

The upper conductive trace area of the circuit board (207) is approximately the same size and shape as the transistor (201) body that is mounted above it. The lower conductive trace area (209) has larger area. The design allows excess heat from the transistor (201) to travel from the upper conductive trace area, through the vias (208) and to spread out to the larger lower conductive trace area (209), which assists dissipation through the high thermal conductivity material layer 3 (210) to the heat sink (202).

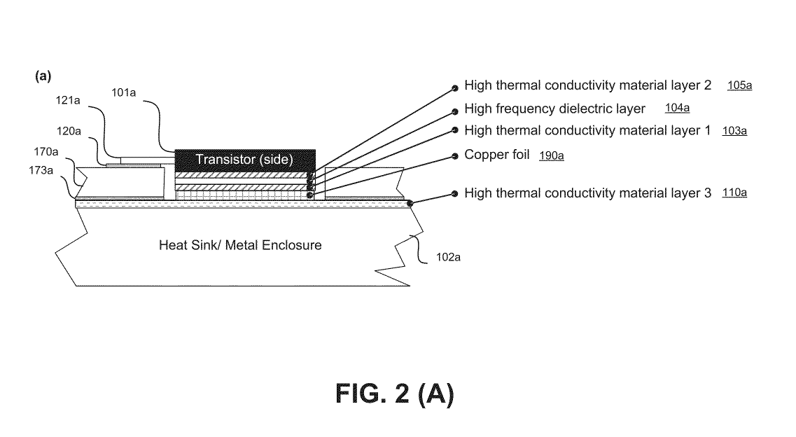

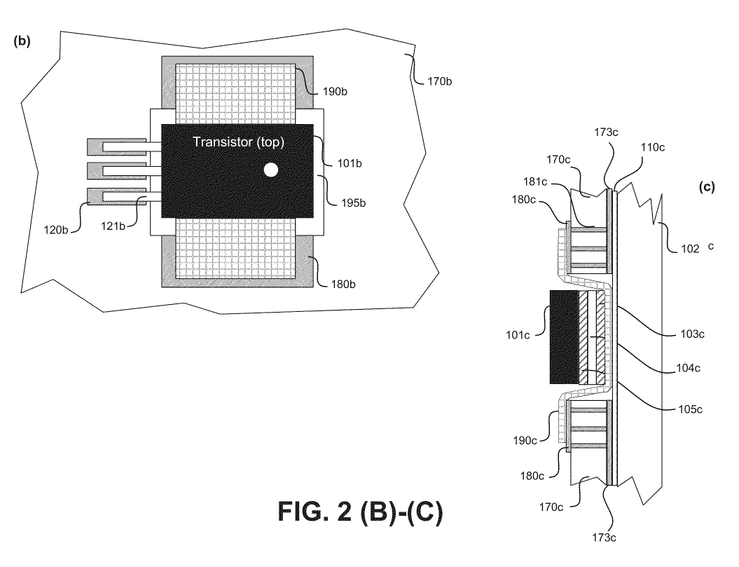

An alternative implementation is shown in FIG. 2. A side view of the transistor (101a) similar to that shown in FIG. 1 is shown in FIG. 2 (a); FIG. 2 (b) shows a top view of the transistor (101b), and FIG. 2 (c) shows and end view of the transistor (101c).

In this alternative implementation the transistor (101a, 101b, 101c) is mounted in an area of the PCB (170a, 170b, 170c) where material has been removed to form a cut-out (195b) that surrounds the transistor (101a, 101b, 101c) body. The transistor (101a, 101b, 101c) legs (example 121a, 121b) are soldered to conductive trace areas (example 120a, 120b) on the PCB (170a, 170b, 170c).

As before, the PCB (170a, 170b, 170c) is mounted to a heat sink/metal enclosure (102a, 102c) with a high thermal conductivity material layer 3 (110a, 110c) between.

The transistor (101a, 101b, 101c) body is attached to the heat sink/metal enclosure (102a, 102c) with a series of layers (105a, 104a, 103a, 190a, 110a for example) of material between. These start with a similar stack composed of a high thermal conductivity material layer 2 (105a, 105c) next to the transistor (101a, 101b, 101c) body, a high frequency dielectric layer (104a, 104c) and a high thermal conductivity layer 1 (103a, 103c). This stack of thermal materials is separated from high thermal conductivity material layer 3 (110a, 110c) by a layer of copper foil (190a, 190b, 190c).

The copper foil (190a, 190b, 190c) is formed such that it is capable of being bent around the transistor (101a, 101b, 101c) body and up onto PCB (170a, 170b, 170c) conductive trace areas (example 180b, 180c) and soldered in place. The conductive trace areas (example 180b, 180c) may optionally be connected to the conductive trace areas (173a, 173c) on the bottom of the PCB with thermal vias (181c) to aid heat transfer from the foil to the heat sink/metal enclosure (102a, 102c).

Alternatively the copper foil may not be formed as shown in 190, but instead remain flat. In this implementation the foil will be soldered or laminated onto the back of the circuit board (173a, 173c).

2. Circuit Design and Circuit Board Layout

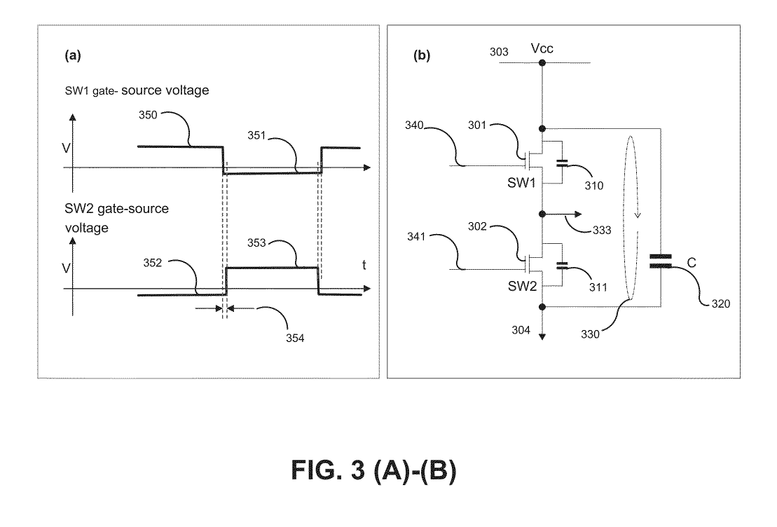

The circuit of FIG. 3 is well known and often called a half bridge. Two switching transistors (SW1, 301 and SW2, 302) are connected together. The source of SW1 (301) is connected to the drain of SW2 (302), forming the circuit output (333). The drain of SW1 (301) is connected to power rail Vcc (303). The source of SW2 (302) is connected to circuit ground (304). The circuit switching is controlled through voltage levels on the gates of SW1 (340) and SW2 (341).

Each transistor is switched in an alternating sequence (350, 351, 352, 353) with a small dead time between (354) during which both transistors SW1, SW2 are in their off states. When transistor SW2 (302) switches on, output (333) transitions from high to low voltage with a fast edge rate that couples into the power rail Vcc, (303) through the parasitic capacitance (310). In order to keep EMI low, decoupling capacitor C (320) is placed in close physical proximity to the drain pin of SW1 (301) and source pin of SW2 (302) to provide a low impedance capacitive path for switching currents (330). This contains the electromagnetic field in a small physical volume to reduce radiation.

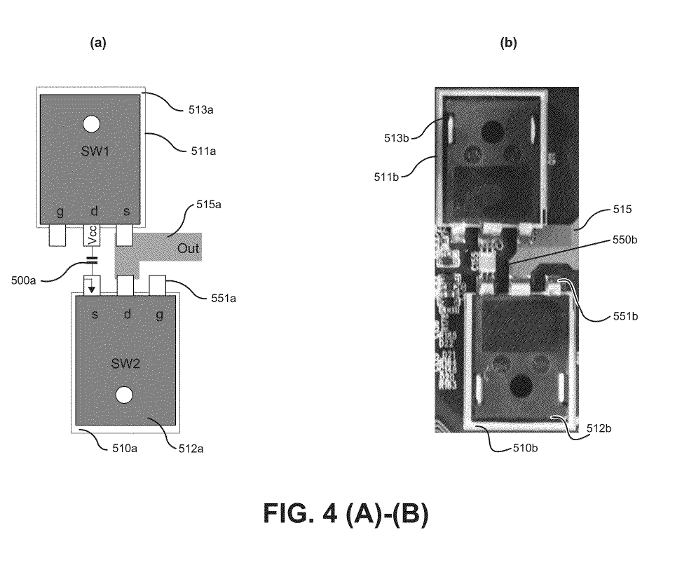

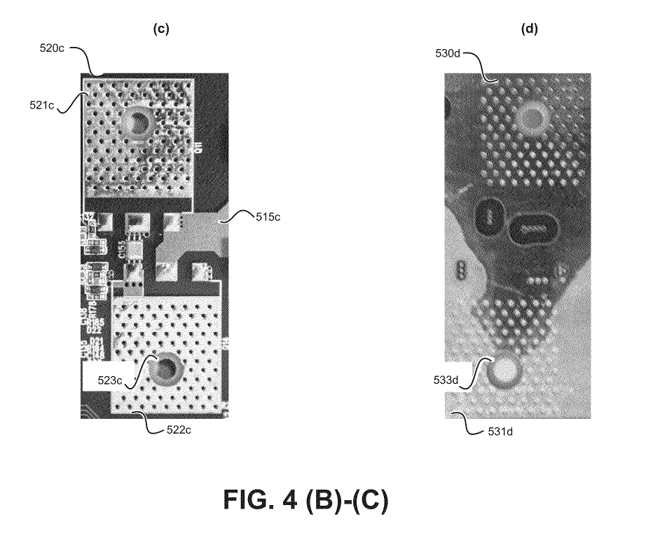

The layout of FIG. 3 is shown in FIG. 4. SW1 and SW2 are shown diagrammatically in (a) as 513a and 512a, and in the photograph of (b) as 513b and 512b. Each transistor (SW1, SW2) is mounted on thermal material (205, 511a, 510a, 511b, 510b). The drain of SW1 and source of SW2 have capacitor C (320, 500a, 550b) connecting between them. The leads of the transistors are cut short and bent through 90 degrees down (551a, 551b, 221) to small pads (220) to reduce parasitic capacitance and to allow SW1 and SW2 to be as physically close to each other as possible.

FIG. 4 (c) shows the same circuit board (520c) as shown in (b) but with transistors SW1 (513b), SW2 (512b) and thermal materials (511b, 510b) removed. The conductive trace area (207, 521c, 522c) and vias (208) are visible.

FIG. 4 (d) shows the bottom side of the circuit board (520c, 530d) showing the lower conductive trace area (209, 531d) of larger area than the upper conductive trace areas (207, 521c, 522c).

Transistors SW1, SW2 (513a, 512a) are bolted through holes (for example, 523c, 533d) to the heat sink to aid heat transfer. Significant keep-out areas are provided around each hole where the conductive trace area coupled to circuit ground (522c, 531d) is not present close to each hole. This ensures that electrical breakdown does not occur between circuit ground and the heat sink potential.

3. Thermal Insulation

Referring to FIG. 1, the circuit board (206) is electrically insulated from and thermally coupled to the heat sink/metal enclosure (202) with high thermal conductivity material layer 3 (210). This is achieved by using commonly available materials with good thermal conductivity and high dielectric breakdown voltage at DC or 50/60 Hz AC.

The transistor (201) is electrically insulated from and thermally coupled to the circuit board (206). Materials such as used for high thermal conductivity material layer 3 (210) cannot be used to insulate the transistor (201) because they typically do not have a high electrical breakdown voltage in the presence of fast edge rates. In this case a high frequency dielectric (204) is used. It should be thin, mechanically strong and have high dielectric breakdown voltage up to the GHz range. Examples, without limitation, include polyimide or polyester films such as Kapton or Mylar. To enhance thermal conductivity it is desirable to add a layer on either side of the high frequency dielectric (204), such as material layer 1 (203) and material layer 2 (205). This can be achieved using thermal paste to form each of the outer layers (203, 205). Alternatively, the three layers (203, 204, 205) may be implemented as a single multi-layer insulator using commercially available material, including, without limitation Berquist Bond-Ply 660P.

This implementation achieves high tolerance of fast edge rates without electrical breakdown, while simultaneously having low thermal resistance and high containment of the electrical field to reduce EMI.

Various other modifications and alterations in the structure and method of operation of this invention will be apparent to those skilled in the art without departing from the scope and the spirit of the invention. Although the invention has been described in connection with specific preferred embodiments, it should be understood that the invention as claimed should not be unduly limited to such specific embodiments. It is intended that the following claims define the scope of the present invention and that structures and methods within the scope of these claims and their equivalents be covered thereby.

What is claimed is:

1. An apparatus including an electronic device mounted on a circuit substrate for fast signal edge rate operation, comprising:
a metal member;
a printed circuit substrate mechanically coupled to said metal member and including
an electrically insulative substrate with mutually opposed first and second substrate sides, and
a first electrically conductive layer disposed on said first substrate side; and
a semiconductor device including at least first and second electrodes with
said first electrode electrically coupled to a portion of said first electrically conductive layer, and
said second electrode mechanically coupled via at least a layer of dielectric material to one or both of said printed circuit substrate and metal member.

2. The apparatus of claim 1, wherein said printed circuit substrate further includes one or more thermal vias between said first and second substrate sides.

3. The apparatus of claim 1, wherein:
said second electrode is mechanically coupled to said printed circuit substrate via said at least a layer of dielectric material and another portion of said first electrically conductive layer; and
said printed circuit substrate further includes
a second electrically conductive layer disposed on said second substrate side, and
one or more thermal vias between said another portion of said first electrically conductive layer and at least a portion of said second electrically conductive layer.

4. The apparatus of claim 1, wherein said printed circuit substrate
further includes a second electrically conductive layer disposed on said second substrate side, and
is mechanically coupled to said metal member via at least a portion of said second electrically conductive layer.

5. The apparatus of claim 1, wherein said printed circuit substrate
further includes a second electrically conductive layer disposed on said second substrate side, and
is mechanically coupled to said metal member via at least a portion of said second electrically conductive layer with a thermally conductive material.

6. The apparatus of claim 1, wherein said printed circuit substrate is mechanically coupled to said metal member via said second substrate side.

7. The apparatus of claim 1, wherein said printed circuit substrate is mechanically coupled to said metal member via said second substrate side with a thermally conductive material.

8. The apparatus of claim 1, wherein said second electrode is mechanically coupled via said at least a layer of dielectric material with a thermally conductive material.

9. A method of mounting an electronic device on a circuit substrate for fast signal edge rate operation, comprising:
mechanically coupling a printed circuit substrate to a metal member, wherein said printed circuit substrate includes
an electrically insulative substrate with mutually opposed first and second substrate sides, and
a first electrically conductive layer disposed on said first substrate side;
electrically coupling a first electrode of a semiconductor device to a portion of said first electrically conductive layer; and
mechanically coupling a second electrode of said semiconductor device via at least a layer of dielectric material to one or both of said printed circuit substrate and metal member.

10. The method of claim 9, wherein said printed circuit substrate further includes one or more thermal vias between said first and second substrate sides.

11. The method of claim 9, wherein:
said mechanically coupling a second electrode of said semiconductor device comprises mechanically coupling said second electrode of said semiconductor device to said printed circuit substrate via said at least a layer of dielectric material and another portion of said first electrically conductive layer; and
said printed circuit substrate further includes
a second electrically conductive layer disposed on said second substrate side, and
one or more thermal vias between said another portion of said first electrically conductive layer and at least a portion of said second electrically conductive layer.

12. The method of claim 9, wherein:
said printed circuit substrate further includes a second electrically conductive layer disposed on said second substrate side; and
said mechanically coupling a printed circuit substrate to a metal member comprises mechanically coupling said printed circuit substrate to said metal member via at least a portion of said second electrically conductive layer.

13. The method of claim 9, wherein:
said printed circuit substrate further includes a second electrically conductive layer disposed on said second substrate side; and
said mechanically coupling a printed circuit substrate to a metal member comprises mechanically coupling said printed circuit substrate to said metal member via at least a portion of said second electrically conductive layer with a thermally conductive material.

14. The method of claim 9, wherein said mechanically coupling a printed circuit substrate to a metal member comprises mechanically coupling said printed circuit substrate to said metal member via said second substrate side.

15. The method of claim 9, wherein said mechanically coupling a printed circuit substrate to a metal member comprises mechanically coupling said printed circuit substrate to said metal member via said second substrate side with a thermally conductive material.

16. The method of claim 9, wherein said mechanically coupling a second electrode of said semiconductor device comprises mechanically coupling said second electrode via said at least a layer of dielectric material with a thermally conductive material.
